(19) United States
(12) Patent Application Publication
(10) Pub. No.: US 2011/0241203 A1
(43) Pub. Date: Oct. 6, 2011

(54) SEMICONDUCTOR MODULE, METHOD FOR MANUFACTURING SEMICONDUCTOR MODULE, AND PORTABLE APPARATUS

(76) Inventors: Mayumi Nakasato, Gifu (JP); Katsumi Ito, Gunna (JP); Ryosuke Usui, Aichi (JP); Yusuke Igarashi, Gunna (JP)

(21) Appl. No.: 13/139,075

(22) PCT Filed: Dec. 10, 2009
(86) PCT No.: PCT/JP2009/006765

§ 371 Date: Jun. 10, 2011

(30) Foreign Application Priority Data
Dec. 10, 2008 (JP) 2008-314960

(51) Int. Cl. H01L 23/498; H01L 21/50

(52) U.S. Cl. 257/737; 438/106; 257/E23.068; 257/E21.499

(57) ABSTRACT

A semiconductor module includes a device mounting board and a semiconductor device. The semiconductor device and the device mounting board are flip-chip connected to each other, and a device electrode provided in the semiconductor device and a substrate electrode provided in the device mounting board are connected by soldering. In a cross section along a line connecting the adjacent substrate electrodes, the width L1 of the substrate electrode is narrower than the width L2 of the device electrode corresponding to the substrate electrode.

### BACKGROUND OF THE INVENTION

1. Technical Field

The present invention relates to a semiconductor module where a semiconductor device is mounted on a substrate. 2. Background Technology

In recent years, with miniaturization and higher performance in electronic devices, demand has been ever greater for further miniaturization of semiconductor devices used in the electronic devices. With such miniaturization of semiconductor devices, it is of absolute necessity that the pitch of electrodes to enable mounting of the semiconductor device on a wiring substrate be made narrower. A known method of surface-mounting the semiconductor device is flip-chip mounting in which external connection electrodes of the semiconductor device are soldered to electrode pads.

### PRIOR ART DOCUMENT

### Patent Document

[Patent Document 1] Japanese Unexamined Patent Application Publication No. 2006-351589.

### DISCLOSURE OF THE INVENTION

### Problems to be Solved by the Invention

In the conventional flip-chip connection, solder used to electrically connect the external connection electrodes of the semiconductor device and the electrode pads of the wiring substrate tend to expand in the lateral direction which is parallel to the substrate plane. Thus, such expanding solder may contact a connection portion between the external connection electrode and the electrode pad which are disposed adjacent to each other, resulting in a short circuit. Accordingly, there are restrictive factors for the narrowing of the pitch between the electrode pads.

Also, the lateral expansion of solder connecting the external connection electrode and the electrode pad presents an impediment to the flow of underfill when the underfill is to be filled into a space between the semiconductor device and the wiring substrate, which may cause the formation of void.

The present invention has been made in view of these problems, and a purpose thereof is to provide a technology that improves the connection reliability of solder connection parts in a semiconductor module which is of a structure such that an external connection electrode of a semiconductor device and an electrode pad of a wiring substrate are joined together using solder which is an example of a conductive connection member. Also, another purpose of the present invention is to prevent the formation of void when underfill is filled into a space between the semiconductor device and the wiring substrate, in a semiconductor module which is of a structure such that the external connection electrode of the semiconductor device and the electrode pad of the wiring substrate are soldered.

### Means for Solving the Problems

One embodiment of the present invention relates to a semiconductor module. The semiconductor module includes: a substrate where a first electrode is provided; a semiconductor device where a second electrode is provided; and a conductive connection member connecting the first electrode and the second electrode, wherein the width of the first electrode is narrower than that of the second electrode corresponding to the first electrode, in a cross section along a line connecting adjacent first electrodes at a shortest distance therebetween, and the height of the first electrode is greater than the width of the first electrode.

This embodiment prevents the conductive connection member used to connect the first electrode and the second electrode from expanding laterally and therefore the size of the conductive connection member falls within the width of the second electrode. Thus, the short circuit between the adjacent first electrodes and between the adjacent second electrodes is suppressed. As a result, the narrowing of the pitch between the first electrodes and between the second electrodes can be achieved without compromising its connection reliability when connected using the conductive connection member.

Since the lateral expansion of the conductive connection member is prevented, the chance that the conductive connection member may obstruct the filling of underfill when the underfill is filled into a space between a device mounting board and the semiconductor device is reduced. Thus, underfill is more likely to infiltrate a gap between the device mounting board and the semiconductor device. As a result, the formation of void at the time of filling the underfill is suppressed.

Since the lateral expansion of the conductive connection member is prevented, the chance that the conductive connection member may obstruct the filling of underfill when the underfill is filled into a space between a device mounting board and the semiconductor device is reduced. Thus, underfill is more likely to infiltrate a gap between the device mounting board and the semiconductor device. As a result, the formation of void at the time of filling the underfill is suppressed.

With regard to the above-described semiconductor module, in the cross section connecting the adjacent first electrodes at the shortest distance therebetween, the conductive connection member may lie within a region connecting a base of the first electrode and an upper side of the second electrode. Also, in the cross section connecting the adjacent first electrodes at the shortest distance therebetween, a ratio (L1/S1) of width L1 of the first electrode over an interval S1 between the adjacent first electrodes may be less than a ratio (L2/S2) of width L2 of the second electrode corresponding to the first electrode over an interval S2 between adjacent second electrodes. Also, in the cross section connecting the adjacent first electrodes at the shortest distance therebetween, a side surface of the first electrode may be tilted towards an electrode forming region. Also, the first electrode may be a bump electrode that protrudes from a wiring layer provided on the substrate towards the semiconductor device. Also, in the cross section connecting the adjacent first electrodes at the shortest distance therebetween, the first electrode may be of an approximately triangular or trapezoidal shape.

Another embodiment of the present invention relates to a portable device. The portable device includes any of the above-described semiconductor module.

Still another embodiment of the present invention relates to a method for fabricating a semiconductor. The method for fabricating a semiconductor module includes: a wiring forming process of patterning a wiring layer, including adjacent substrate electrodes, on one main surface of a substrate; and a device mounting process of mounting a semiconductor device in a manner such that (1) a device electrode so provided in the semiconductor device as to correspond to the substrate electrode and (2) the substrate electrode are connected using a conductive connection member, wherein the substrate electrode is formed, in the wiring forming process, in a manner such that the width of the substrate electrode is narrower than that of the device electrode corresponding to the substrate electrode, in a cross section along a line connecting the adjacent substrate electrodes at a shortest distance therebetween.

### Effect of the Invention

The present invention prevents the conductive connection member used to connect the external connection electrode of the semiconductor device and the electrode pad of the wiring substrate from expanding laterally and therefore the insulation between the adjacent connection portions of the conductive connection member. As a result, the connection reliability of solder connection parts is improved.

### BRIEF DESCRIPTION OF THE DRAWINGS

FIG. 1 is a cross-sectional view showing a structure of a semiconductor module according to a first embodiment of the present invention.

FIG. 2 is a plan view showing an exemplary pattern of a wiring layer including a substrate electrode.

FIGS. 3A to 3E are cross-sectional views showing a process in a method for fabricating a semiconductor module according to a first embodiment.

FIGS. 4A to 4D are cross-sectional views showing a process in a method for fabricating a semiconductor module according to a first embodiment.

FIG. 5 is a plan view showing another exemplary pattern of a wiring layer including a substrate electrode.

FIG. 6 is a cross-sectional view showing a structure of a semiconductor module according to a second embodiment of the present invention.

FIGS. 7A and 7B are cross-sectional views showing a process in a method for fabricating a semiconductor module according to a second embodiment.

FIGS. 8A to 8D are cross-sectional views showing a process in a method for fabricating a semiconductor module according to a second embodiment.

FIGS. 9A to 9C are cross-sectional views showing a process in a method for fabricating a semiconductor module according to a second embodiment.

FIGS. 10A and 10B are cross-sectional views showing a process in a method for fabricating a semiconductor module according to a second embodiment.

FIGS. 11A to 11C are cross-sectional views showing a process in a method for fabricating a semiconductor module according to a second embodiment.

FIG. 12 is a cross-sectional view showing a structure of a semiconductor module according to a modification.

FIG. 13 illustrates a structure of a mobile phone equipped with a semiconductor module according to an embodiment of the present invention.

FIG. 14 is a partial cross-sectional view of the mobile phone shown in FIG. 13.

### BEST MODE FOR CARRYING OUT THE INVENTION

Hereinbelow, the embodiments will be described with reference to the accompanying drawings. Note that in all of the Figures the same reference numerals are given to the same components and the repeated description thereof is omitted as appropriate.

### First Embodiment

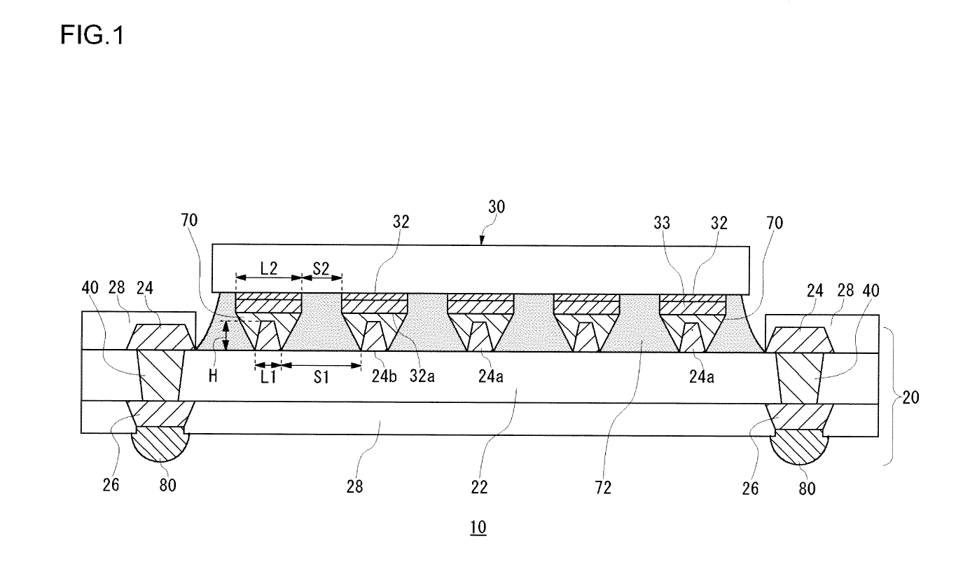

FIG. 1 is a cross-sectional view showing a structure of a semiconductor module according to a first embodiment of the present invention. The semiconductor module 10 includes a device mounting board 20 and a semiconductor device 30. The semiconductor device 30 is mounted on the device mounting board 20 in such a manner that an electrode forming surface on which a device electrode (external electrode terminal) is formed is positioned downward. Then the device electrode and an electrode terminal provided on the device mounting board 20 are electrically connected to each other using solder. In other words, the semiconductor device 30 is flip-chip connected to the device mounting board 20.

The device mounting board 20 includes an insulating resin layer 22, a wiring layer 24 provided on one main surface (semiconductor device mounting side) of the insulating resin layer 22, a protective layer 28, a wiring layer 26 provided on the other main surface of the insulating layer 22, a protective layer 28, and a solder ball 80.

The material preferably used for the insulating resin layer 22 may be, for instance, a thermosetting resin such as a melamine derivative (e.g., FT resin), liquid-crystal polymer, epoxy resin, PPE resin, polyimide resin, fluorine resin, phenol resin or polyamide bismaleimide, or the like. From the viewpoint of improving the heat radiation of the semiconductor module 10, it is preferable that the insulating resin layer 22 has a high thermal conductivity. In this respect, it is desirable that the insulating resin layer 22 contains, as a high thermal conductive filler, silver, bismuth, copper, aluminum, magnesium, tin, zinc, or an alloy thereof. Also, the insulating resin layer 22 may be formed of glass epoxy resin in which glass cloth is embedded into the insulating resin layer 22 in order to reduce the difference in thermal expansion coefficients between the insulating resin layer 22 and the semiconductor device 30 or in order to enhance the rigidity of the insulating resin layer 22.

The wiring layer 24 has a predetermined pattern and is provided on the one main surface of the insulating resin layer 22. The wiring layer 24 is formed of a conducive material such as copper. The wiring layer 24 includes substrate electrodes 24a (electrode pads) used to connect the semiconductor device 30. The substrate electrode 24a is equivalent to “first electrode” set forth in the claim phraseology of the present invention. The shape of the substrate electrode 24a will be discussed later.

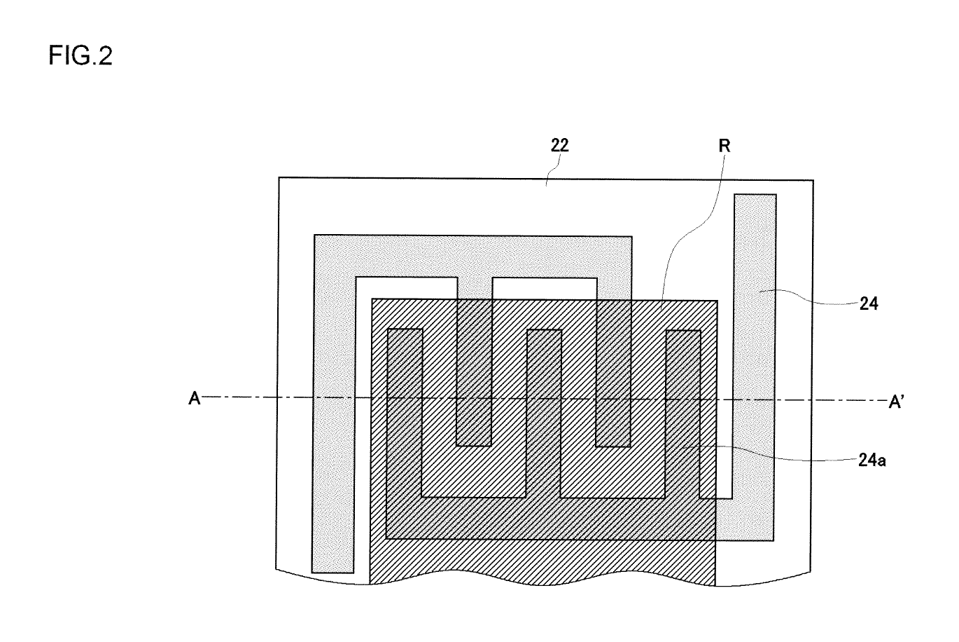

FIG. 2 is a plan view showing an exemplary pattern of the wiring layer 24 including the substrate electrode 24a. The substrate electrode 24a is of a comb-teeth shape and is a comb electrode formed in such a manner that a part of the substrate electrode 24 protrudes from the wiring layer 24. The substrate electrode 24a (comb electrode) is of a structure such that pairs of comb electrodes are disposed counter to each other and a comb teeth of one electrode and a comb teeth of another comb electrode are provided side by side. The Solder used for the flip-chip connection are formed on the substrate electrode 24a. The line A-A′ of FIG. 2 corresponds to a line connecting adjacent substrate electrodes 24a at the shortest distance therebetween, and FIG. 1 corresponds to a cross sectional view taken along the line A-A′ of FIG. 2. A region R indicates a region where the semiconductor device 30 is mounted.

Referring back to FIG. 1, the protective layer 28 is provided on one main surface of the insulating resin layer 22 in such a manner as to cover the wiring layer 24 excluding the substrate electrodes 24a. The protective layer 28 suppresses the oxidation of the wiring layer 24 and the deterioration of the insulating resin layer 22. The protective layer 28 may be formed of a photo solder resist, for instance, and the thickness of the protective layer 28 may be 10 μm to 50 μm, for instance.

The wiring layer 26 has a predetermined pattern and is provided on the other main surface of the insulating resin layer 22. The wiring layer 26 is formed of a conductive material such as copper. The thickness of the wiring layer 24 and and the wiring layer 26 may be 10 μm to 25 μm, for instance.

Via conductors 40 that penetrate the insulating resin layer 22 are provided at predetermined positions. The via conductor 40 is formed by a copper plating, for instance. The wiring layer 24 and the wiring layer 26 are electrically connected to each other by the via conductors 40.

The protective layer 28 is also provided on the other main surface of the insulating resin layer 22 in such a manner as to cover the wiring layer 26. The protective layer 28 suppresses the oxidation of the wiring layer 26 and the deterioration of the insulating resin layer 22. The protective layer 28 has openings in which the solder balls 80 are to be mounted on predetermined regions (land areas) of the wiring layer 26. The solder ball 80 is connected to the wiring layer 26 in an opening provided in protective layer 28, and the semiconductor module 10 is connected to a not-shown printed wiring substrate by the solder balls 80.

The semiconductor device 30 is an active device such as an integrated circuit (IC) or a large-scale integrated circuit (LSI). In association with the substrate electrode 24 provided on the device mounting board 20, a device electrode 32 (electrode pad) is provided on the electrode forming surface of the semiconductor device 30, and a copper pillar 33 is formed on the surface of the device electrode 32. The cross sectional shape of the pillar 32 is similar to that of the device electrode 32. The copper pillar 33 and the substrate electrode 24a are connected via solder 70. The device electrode 32 and the copper pillar 33 are equivalent to “second electrode” set forth in the claim phraseology of the present invention. Note that the device electrode 32 and the substrate electrode 24a may be connected via the solder 70 without the medium of the copper pillar 33 held between the device electrode 32 and the solder 70. Also, the solder 70 is equivalent to “conductive connection member” set forth in the claim phraseology of the present invention.

Underfill 72 is filled in a space between the semiconductor device 30 and the device mounting board 20. The underfill 72 not only protects a joint between the substrate electrode 24a and the device electrode 32 but also relaxes the stress acting between the semiconductor device 30 and the device mounting substrate 20. Thus the connection reliability of the semiconductor module 10 is improved.

A description is now given of the features of the base electrodes 24a.

In the cross section that connects adjacent substrate electrodes 24a at the shortest distance therebetween, width L1 of the substrate electrode 24a is narrower than width L2 of the device electrode 32 corresponding to the substrate electrode 24a (i.e., disposed counter to the substrate electrode 24a). More preferably, where the interval between the adjacent substrate electrodes 24a is denoted by S1 and the interval between the adjacent device electrodes 32 is denoted by S2, an L/S ratio (L1/S1) of the substrate electrode 24a is less than an L/S ratio (L2/S2) of the device electrode 32. Also, the height H of the substrate electrode 24a is greater than the width L1 of the substrate electrode 24a and therefore a relation H>L1 holds.

Moreover, the side surface of the substrate electrode 24a is tilted towards the inward side of the substrate electrode 24a; namely, the side surface of the substrate 24a is tilted inward. In other words, the angle formed between the substrate surface of the device mounting board 20 and the side surface of the substrate electrode 24a is an acute angle. Although the shape of the substrate electrode 24a is not limited to any particular one as long as the above condition is met, the substrate electrode 24a is of an approximately triangular or trapezoidal shape, for example, in the cross section connecting the adjacent substrate electrodes 24a.

The above-described structure prevents the solder 70 from expanding laterally (in a surface direction of the device mounting board 20) and therefore, the size of the solder 70 falls within the width L2 of the device electrode 32. More specifically, the solder 70 is disposed within a region connecting a base 24b of the substrate electrode 24a (i.e., a part of the insulating resin layer 22 which is in contact with the substrate electrode 24a) and an upper side 32a of the device electrode 32. Thus, the short circuit between adjacent substrate electrodes 24a and between adjacent device electrodes 32 is suppressed. As a result, the narrowing of the pitch between the substrate electrodes 24a and between the device electrodes 32 can be achieved without compromising its connection reliability when connected using solder.

Since the lateral expansion of the solder 70 is prevented, the chance that the solder 70 may obstruct the filling of underfill 72 when the underfill 72 is filled into a space between the device mounting board 20 and the semiconductor device 30 is reduced. Thus, underfill 70 is more likely to infiltrate a gap between the device mounting board 20 and the semiconductor device 30. As a result, the formation of void at the time of filling the underfill 72 is suppressed.

Since the structure is such that the height H of the substrate electrode 24a is greater than the width L1 of the substrate electrode 24a, the width L1 of the substrate electrode 24a can be narrowed. Thus, the narrowing of the pitch of adjacent substrate electrodes 24a or high-density packaging can be achieved.

(Method for Fabricating Semiconductor Modules According to the First Embodiment)

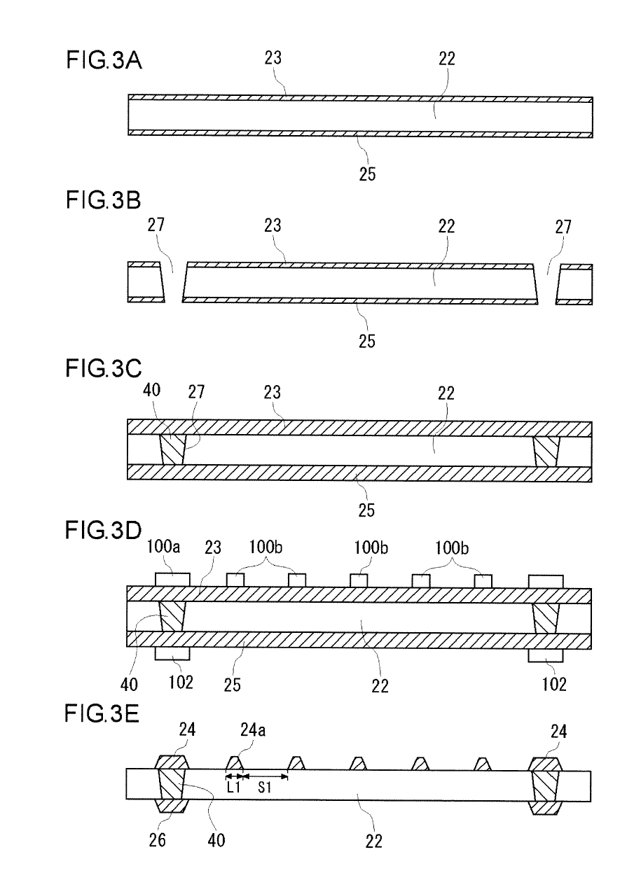

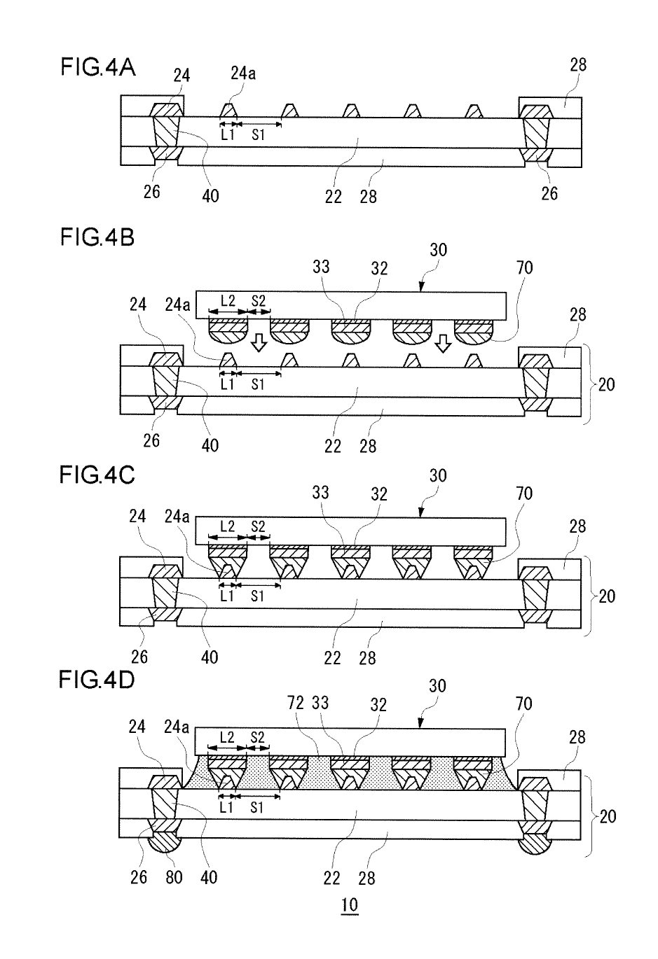

A method for manufacturing semiconductor modules 10 according to the first embodiment is described with reference to FIG. 3A to FIG. 4D.

As illustrated in FIG. 3A, an insulating resin layer 22 on one main surface of which a copper foil 23 is affixed and on the other surface of which a copper foil 25 is affixed is prepared.

Then, as shown in FIG. 3B, via holes 27 are formed at predetermined regions of the insulating layer 22 and the copper foils 23 and 25 by a drill or laser process.

Then, as illustrated in FIG. 3C, the via holes 27 are filled with copper by using an electroless plating method and an electrolytic plating method, thereby forming via conductors 40. At the same time, the copper foils 23 and 25 provided on the both main surfaces of the insulating resin layer 22 are thickened.

Then, as illustrated in FIG. 3D, resist patterns 100a, 100b and 102 corresponding respectively to the wiring layers 24, 24a and 26 are formed on the copper foils 23 and 25.

Then, as illustrated in FIG. 3E, wet etching is done using the resist patterns 100a and 100b as masks and thereby a wiring layer 24 of a predetermined pattern including the substrate electrodes 24a is formed on one main surface of the insulating resin layer 22. At this time, patterning is performed such that in the cross section connecting the adjacent substrate electrodes 24a, the width L1 of the substrate electrode 24a is narrower than the width L2 of the device electrode 32 corresponding to this substrate electrode 24a. More preferably, patterning is performed such that in the cross section connecting the adjacent substrate electrodes 24a, the ratio (L1/S1) of the width L1 of the substrate electrode 24a to the interval S1 between the adjacent substrate electrodes 24a is less than the ratio (L2/S2) of the width L2 of the device electrode corresponding to the substrate electrode 24a to the interval S2 between the adjacent device electrodes. Also, patterning is performed such that the side surface of the substrate electrode 24a is tilted towards the inward side of an electrode forming region of the substrate electrode 24a.

On the other hand, wet etching is done using the resists 102 as a mask and thereby a wiring layer 26 is formed on the other main surface of the insulating resin layer 22.

Then, as illustrated in FIG. 4A, a photo solder resist is stacked and then a protective layer 28 excluding the substrate electrodes 24a is formed on one main surface of the insulating resin layer 22, using a known photolithography method. Also, a protective layer 28 having openings in which the land areas of the wiring layer 26 are exposed is formed in the other main surface of the insulating resin layer 22.

Then, as illustrated in FIG. 4B, prepared is a semiconductor device 30 where device electrodes 32 and copper pillars 33 are provided on the electrode forming surfaces of the semiconductor device 30 and solder 70 are mounted on the copper pillars 33. Then, the semiconductor device 30 is mounted on top of a device mounting board 20. The copper pillars 33 may be formed using a plating method, for instance.

Then, as illustrated in FIG. 4C, a reflow process is performed with the semiconductor device 20 mounted on top of the device mounting board 20. That is, in this reflow process, the copper pillar 33 and substrate electrode 24 which are to be placed counter to each other are joined together by way of the solder 70.

Then, as illustrated in FIG. 4D, underfill 72 is filled into a space between the semiconductor device 30 and the device mounting board 20. Also, solder balls 80 are mounted on the wiring layer 26 in the openings provided in the protective layer 28.

A semiconductor module 10 according to the first embodiment can be manufactured through the processes as described above. Though not shown here, a sealing resin layer may be used to seal the semiconductor element 1300 by using a transfer mold method or the like.

(Another Exemplary Pattern of Wiring Layer)

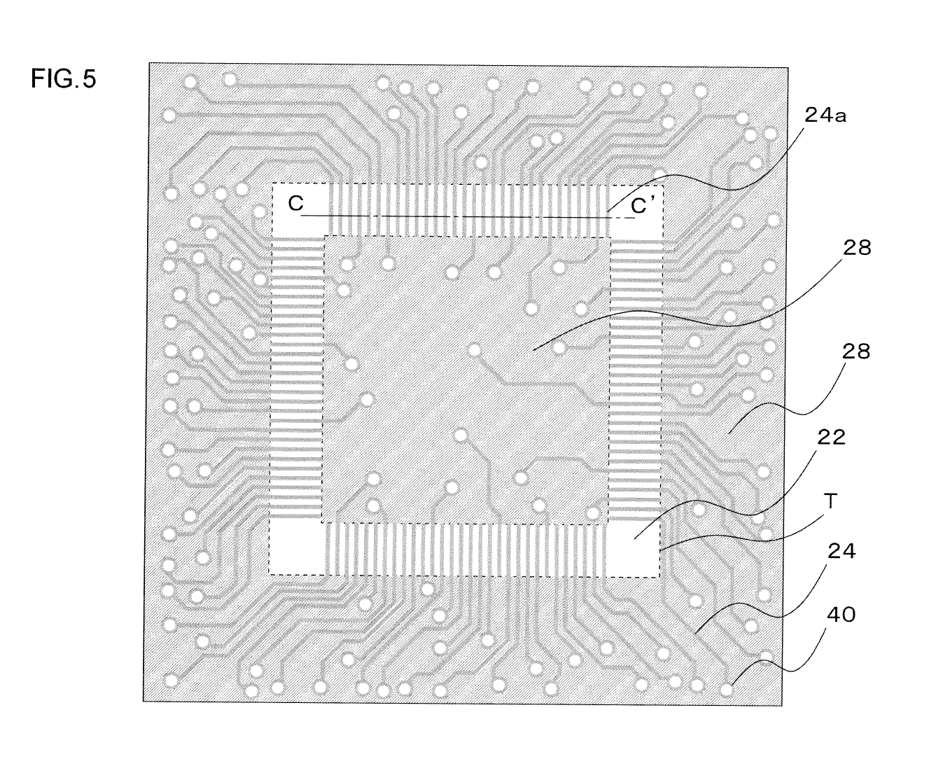

FIG. 5 is a plan view showing another exemplary pattern of a wiring layer including a substrate electrode. Openings T corresponding to the periphery of a semiconductor device to be mounted are provided in a protective layer 28 provided on one main surface of the insulating layer 22. Substrate electrodes 24a and an insulating layer 22 are exposed through the openings T. The substrate electrode 24a is formed on one end of a wiring layer 24, whereas a via conductor 40 is connected to the other end of the wiring layer 24. In other words, circuit wiring is extended from the substrate electrode 24a to the via conductor 40 through the wiring layer 24. The via conductors 40 are placed at predetermined positions within a mounting region of the semiconductor device (inside the opening T of FIG. 5) and outside the mounting region of the semiconductor device (outside the opening of FIG. 5).

A plurality of substrate electrodes 24a are provided side by side in the opening T. A longitudinal direction of the substrate electrode 24 is placed in such a manner as to pass across the opening T. The line C-C′ of FIG. 5 corresponds to a line connecting adjacent substrate electrodes 24 at the shortest distance therebetween, and the mounting region of the semiconductor device 30 of FIG. 1 corresponds to a cross sectional view taken along the line C-C′.

### Second Embodiment

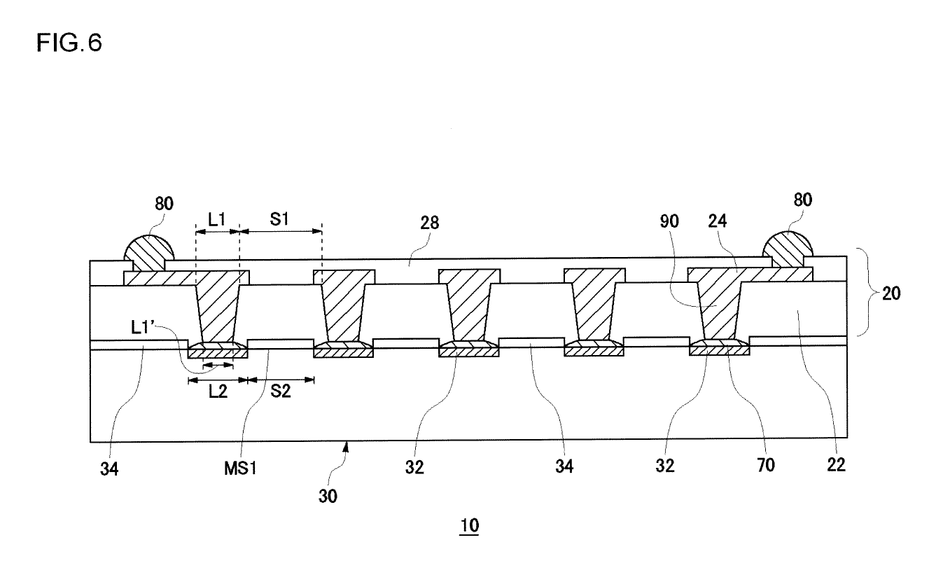

FIG. 6 is a cross-sectional view showing a structure of a semiconductor module according to a second embodiment of the present invention.

The semiconductor module 10 includes a device mounting board 20 and a semiconductor device 30.

The semiconductor device 30 is formed using a P-type silicon wafer, for instance. A device electrode 32 connected to an integrated circuit is provided on a main surface MS1 which is a mounting surface. The device electrode 32 is made of a metal such as aluminum (Al) or copper (Cu). The device electrode 32 is equivalent to “second electrode” set forth in the claim phraseology of the present invention.

A protective layer 34 is formed on top of the main surface MS1 of the semiconductor device 30 in such a manner that the device electrodes 32 are exposed there. As the protective layer 34, a silicon dioxide film (SiO₂), a silicon nitride film (SiN), a polyimide film (PI) film or the like is preferably used.

The device mounting board 20 is such that an insulating resin layer 22, a wiring layer 24 (rewiring) provided on one main surface of the insulating resin layer 22 opposite to the semiconductor device mounting 30, a wiring layer 24 are formed integrally with one another, and the device mounting board 20 includes bump electrodes 90 protruding towards the insulating resin layer 22. The bump electrode 90 is equivalent to “first electrode” set forth in the claim phraseology of the present invention. FIG. 6 is also a cross-sectional view along a line that connects the adjacent bump electrodes 90 at the shortest distance therebetween.

The insulating resin layer 30 is formed of, for example, a material that develops plastic flow when heated or pressurized. An example of the material that develops plastic flow when heated or pressurized is epoxy-based thermosetting resin. The epoxy-based thermosetting resin to be used for the insulating resin layer 22 may be, for example, one having viscosity of 1 kPa·s under the conditions of a temperature of 160° C. and a pressure of 8 MPa. If a pressure of 5 to 15 MPa is applied to this epoxy-based thermosetting resin at a temperature of 160° C., then the viscosity of the resin will drop to about ⅛ of the viscosity thereof with no pressurization. In contrast to this, an epoxy resin in B stage before thermosetting has no viscosity, similarly to a case when the resin is not pressurized, under a condition that the temperature is less than or equal to a glass transition temperature Tg. And the epoxy resin develops no viscosity even when pressurized under a condition that the temperature is less than or equal to the glass transition temperature Tg. Also, this epoxy-based thermosetting resin is a dielectric substance having a permittivity of about 3 to 4.

The wiring layer 24, which is provided on the main surface of the wiring layer 22 opposite to the semiconductor device 30, is formed of a conductive material, preferably a rolled metal or more preferably a rolled copper. The rolled copper performs excellently as a material for rewiring because it has greater mechanical strength than a copper film formed by plating or the like. The wiring layer 24 may be formed of electrolyte copper or the like. In the present embodiment, the wiring layer 24 and the bump electrode 90 are integrally formed with each other and such a structure as this assures the connection between the wiring layer 24 and the bump electrode 60.

The overall shape of the bump electrode 90 is such that the bump electrode 90 grows smaller in diameter toward the tip thereof. In other words, the side surface of the bump electrode 90 is tilted towards the inward side of the electrode forming region and is therefore tapered. In other words, the angle formed between the surface of the wiring layer 24 and the side surface of the bump electrode 90 is an acute angle. The diameter of tip (top surface) of the bump electrode 90 and the diameter of bottom surface thereof are about 45 μmφ and about 60 μmφ, respectively. Also, the height of the bump electrode 90 is 20 μm, for instance. The top surface of the bump electrode 90 and the device electrode 32 corresponding to the bump electrode 90 are bonded together by solder 70.

In the cross section that connects adjacent bump electrodes 90 at the shortest distance therebetween, width L1 of the base of the bump electrode 90 is narrower than width L2 of the device electrode 32 corresponding to the bump electrode 90. More preferably, where the interval between the adjacent bump electrodes 90 is denoted by S1 and the interval between the adjacent device electrodes 32 is denoted by S2, the L/S ratio (L1/S1) of the bump electrode 90 is less than the L/S ratio (L2/S2) of the device electrode 32. Also, since the overall shape of the bump electrode 90 is such that the bump electrode 90 grows smaller in diameter toward the tip thereof, width L1′ of the top surface of the bump electrode 90 is smaller than the width L1 of the base of the bump electrode 90.

A protective layer 28 is provided on one main surface of the wiring layer 24 opposite to the insulating resin layer 22. This protective layer 28 protects the wiring layer 24 against oxidation or the like. The protective layer 28 may be a solder resist layer, for instance. Openings are formed in predetermined regions of the protective layer 28, and the wiring layer 24 is partially exposed there. A solder ball 80 functioning as an external connection electrode is formed in the opening, and the solder ball 80 and the wiring layer 24 are electrically connected to each other. The positions in which the solder balls 80 are formed, namely, regions in which the openings are formed are, for instance, targeted positions where circuit wiring is extended through the rewiring (wiring layer 24).

(Method for Fabricating Semiconductor Modules According to the Second Embodiment)

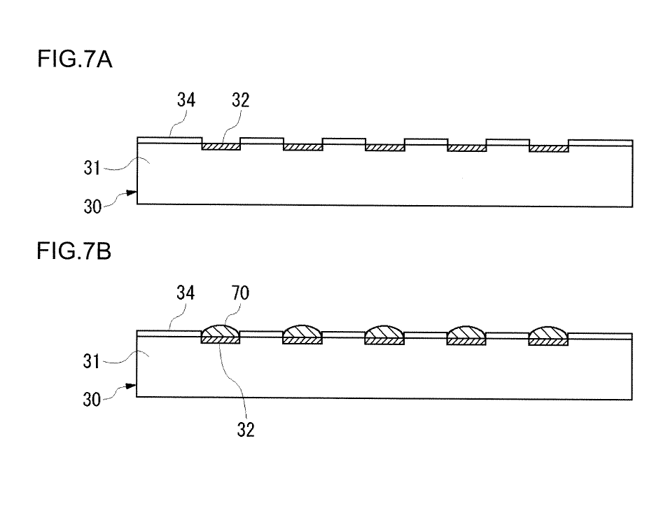

A method for manufacturing semiconductor modules 10 according to the second embodiment is described with reference to FIG. 7A to FIG. 11C.

As illustrated in FIG. 7A, prepared is a semiconductor device 30 in which device electrodes 32 and a protective layer 34 are beforehand formed on one main surface of a semiconductor substrate 31. More specifically, a predetermined integrated circuit is formed on one main surface of the semiconductor substrate 31, such as a P-type silicon substrate, and the device electrodes 32 are formed in the outer periphery of the integrated circuit by the use of a semiconductor manufacturing process that combines known techniques including lithography, etching, ion implantation, film formation and thermal processing.

The device electrode 32 is made of a metal such as aluminum or copper. Then an insulating protective layer 34 to protect the semiconductor substrate 31 is formed on the main surface of the semiconductor substrate 31 excluding the device electrodes 32. As the protective film 34, a silicon dioxide film (SiO₂), a silicon nitride film (SiN), a polyimide film (PI) or the like is preferably used.

Then, as illustrated in FIG. 7B, the solders 70 are mounted in the openings of the protective layer 34 by using a screen printing method. More specifically, the solders 70 are formed by printing soldering paste, which is a pasty mixture of resin and solder material, in desired positions through a screen mask and then heating the printed paste to a solder melting temperature.

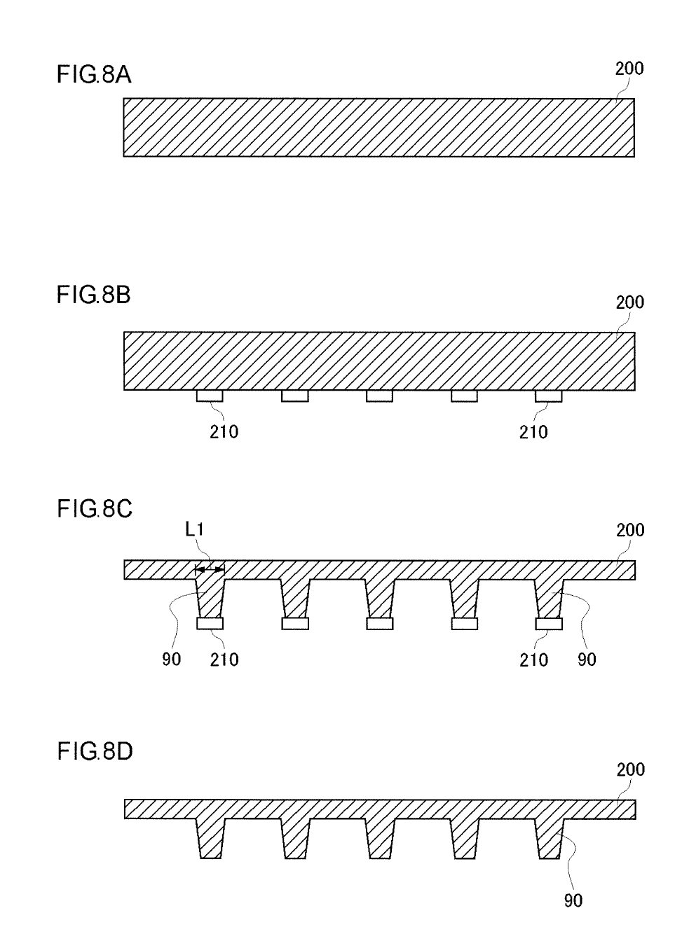

On the other hand, as illustrated in FIG. 8A, a copper sheet 200 is prepared as a metallic sheet having a thickness greater than at least the sum of the height of the bump electrode 90 and the thickness of the wiring layer 24 as shown in FIG. 6. The thickness of the copper sheet 200 is 125 □m, for instance. The rolled metal formed of a rolled copper is used as the copper sheet 200.

Then, as illustrated in FIG. 8B, resists 210 are formed selectively in alignment with a pattern that corresponds to a predetermined formation region of bump electrodes using a lithography method. More specifically, a resist film of predetermined film thickness is affixed to the copper sheet 200 by a laminator apparatus, and it is then subjected to exposure using a photo mask having the pattern of bump electrodes 90. After this, the resists 210 are selectively formed on the copper sheet 200 by a development. To improve the adhesion of the resists 210 to the copper sheet 200, it is desirable that a pretreatment, such as grinding, cleaning and the like, be performed as necessary on the surface of the copper sheet 200 before the lamination of the resist film thereon. To protect the copper sheet 200, it is desirable that a resist protective film (not shown) is formed on the entire surface (top side) opposite to the surface on which the resists 210 have been provided.

Then, as illustrated in FIG. 8C, using the resists 210 as a mask, the bump electrodes 90 of a predetermined circular truncated cone pattern protruding from the surface of the copper sheet 200 is formed by performing a wet etching on the copper sheet 200, in which a chemical such as ferric chloride solution or the like is used. In so doing, the bump electrode 90 is formed such that the diameter (dimensions) of the bump electrode 90 is smaller toward the tip part thereof; namely, the surface side of the bump electrode 90 is tapered. The wet etching is performed so that the diameter (width) L1 of the base of the bump electrode 90 is smaller than the width L2 (See FIG. 1) of the device electrode 32 corresponding to the bump electrode 90. The diameter of the base, the diameter of the top surface, and the height of the bump electrode 90 according to the present embodiment are 100 to 140 μmφ, 50 μmφ, and 20 to 25 μmφ, respectively, for instance.

Then, as shown in FIG. 8D, the resists 210 and the resist protective film are removed using a remover. The bump electrodes 90 are integrally formed on the copper sheet 200 through a process as described above. It is to be noted that a metal mask of silver (Ag) may be used instead of the resist 210. In such a case, etching selectivity in relation to the copper sheet 200 can be amply secured, so that finer patterning of the bump electrodes 90 can be realized.

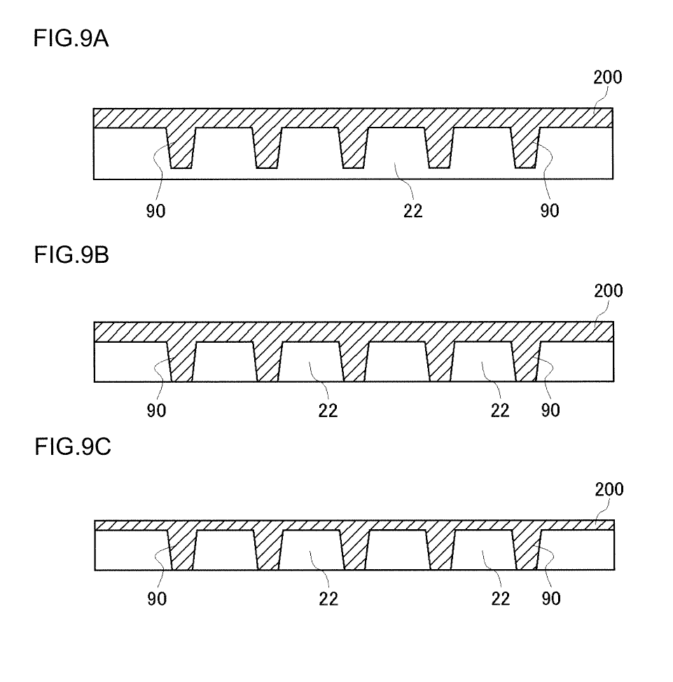

Then, as shown in FIG. 9A, an insulating resin layer 22 is stacked on the surface of the copper sheet 200 on the side where the bump electrodes 90 are provided, using a vacuum laminating method. As described above, an insulating material that develops plasticity or becomes deformed when pressurized or heated is used as the insulating resin layer 22.

Then, as shown in FIG. 9B, the insulating resin layer 22 is turned into thin film by the use of O₂ plasma etching so that the top surface of the bump electrode 90 is exposed.

Then, as shown in FIG. 9C, the surface of the copper sheet 200 on a side opposite to the side where the bump electrodes 90 are provided is etched back using a chemical such as ferric chloride solution or the like and thereby the copper sheet 200 is turned into thin film. At this time, a resist protective film (not shown) is formed on the side of the copper sheet 200 where the bump electrodes 90 are provided, to protect the bump electrodes 90 and the copper sheet 200. As a result, formed is the copper sheet 200 which is so processed as to have a predetermined thickness (thickness of the wiring layer 24) and with which predetermined bump electrodes 90 are provided integrally. The thickness of the copper sheet 200 according to the present embodiment is about 20 μm.

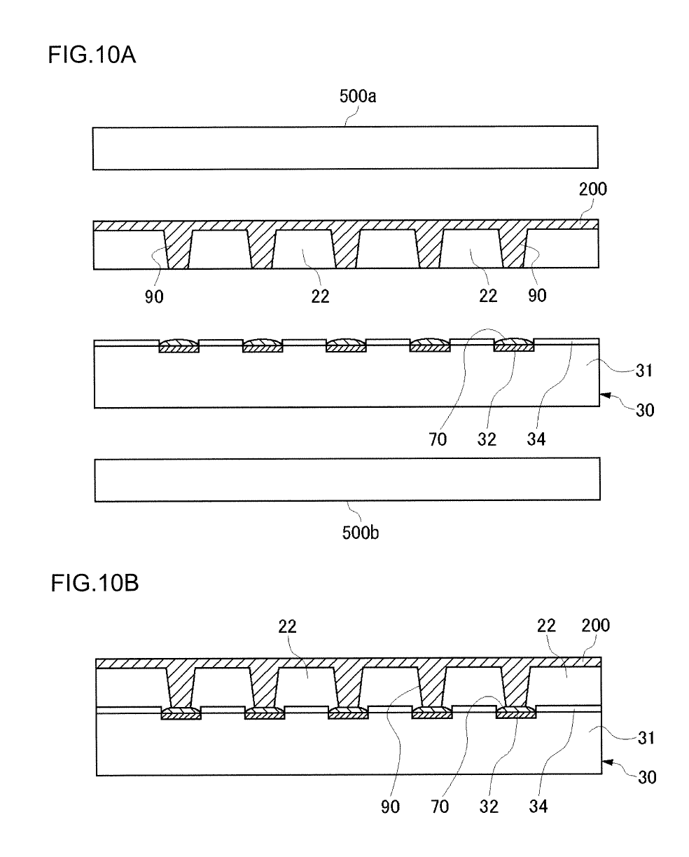

Then, as illustrated in FIG. 10A, the semiconductor device 30 and the copper sheet 200 formed integrally with the bump electrodes 90 are placed between a pair of flat plates 500a and 500b constituting a press machine. At this time, the positioning of the bump electrodes 90 and the device electrodes that correspond to each other, respectively, are done.

Then, as shown in FIG. 10B, the semiconductor device 30 and the copper sheet 200 are press-formed and pressed-bonded by the use of a press machine, in a state where the corresponding bump electrodes 90 and device electrodes 32 are abutted against each other. The pressure and temperature under which the semiconductor device 30 and the copper sheet 200 are press-formed are about 17 kN and about 200° C., respectively. During this process or after this process, the solder 70 is melted by a reflow process, and the corresponding bump electrodes 90 and device electrodes 90 are bonded together. The wettability of the melted solder 70 relative to the top surface of the bump electrode 90 is higher than that of the melted solder 70 relative to the insulating resin layer 22. Thus, the solder 70 is pulled to the top surface of the bump electrode 90 and therefore the width of the solder 70 lies within the top surface of the bump electrode 90 in the vicinity of the top surface of the bump electrode 90.

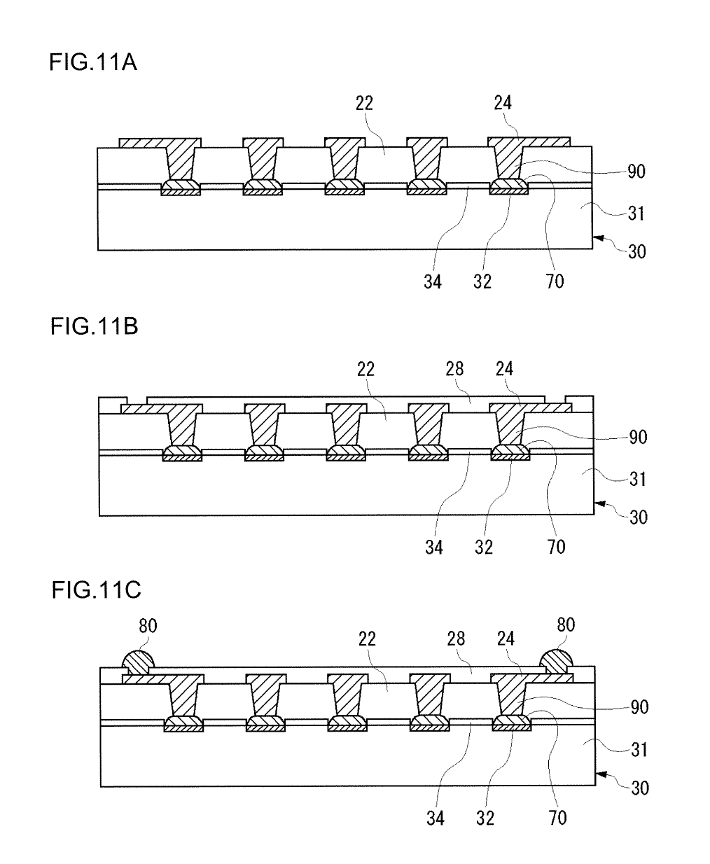

Then, as shown in FIG. 11A, a wiring layer 24 (rewiring) is formed by processing the copper sheet 200 into a predetermined pattern using a lithography and etching technique.

Then, as shown in FIG. 11B, a protective layer (photo solder resist layer) 28 is laminated on the wiring layer 24 and the insulating resin layer 22 and then openings are provided in predetermined regions (solder-ball mounting regions) of the protective layer 28 using a photolithography method. The protective layer 28 functions as a protective film for the wiring layer 24. Epoxy resin or the like is used for the protective layer 28, and the film thickness of the protective layer 28 is about 40 μm, for instance.

Then, as shown in FIG. 11C, the solder balls 80 are mounted in the openings of the protective layer 28 by using a screen printing method. More specifically, the solder balls 80 are formed by printing soldering paste, which is a pasty mixture of resin and solder material, in desired positions through a screen mask and then heating the printed paste to a solder melting temperature.

A semiconductor module according to the second embodiment can be manufactured through the processes as described above.

By employing the semiconductor module 10 as described above, the size of the solder 70 falls within the width L1′ of the top surface of the bump electrode 90, in the vicinity of the top surface of the bump electrode 90. The width L1′ of the top surface of the bump electrode 90 is smaller than the width L1 of the base of the bump electrode 90, and the width L1 of the base of the bump electrode 90 is smaller than the width L2 of the device electrode 32 corresponding to the bump electrode 90. In other words, the solder 70 is prevented from expanding laterally (in the surface direction of the device mounting board 20) so that the width of the solder 70 at a bump electrode 90 side can lie within the width L2 of the device electrode 32. As a result, the narrowing of the pitch between the substrate electrodes 24a and between the device electrodes 32 can be achieved without compromising its connection reliability when connected using solder.

In the present embodiment, the solder 70 is provided between the top surface of the bump electrode 90 and the device electrode 32, and the solder 70 is in contact with the top surface of the bump electrode 90. Note, however, that the solder 70 may be in contact with the side surface of the bump electrode 90 as long as it lies within the width L2 of the device electrode 32.

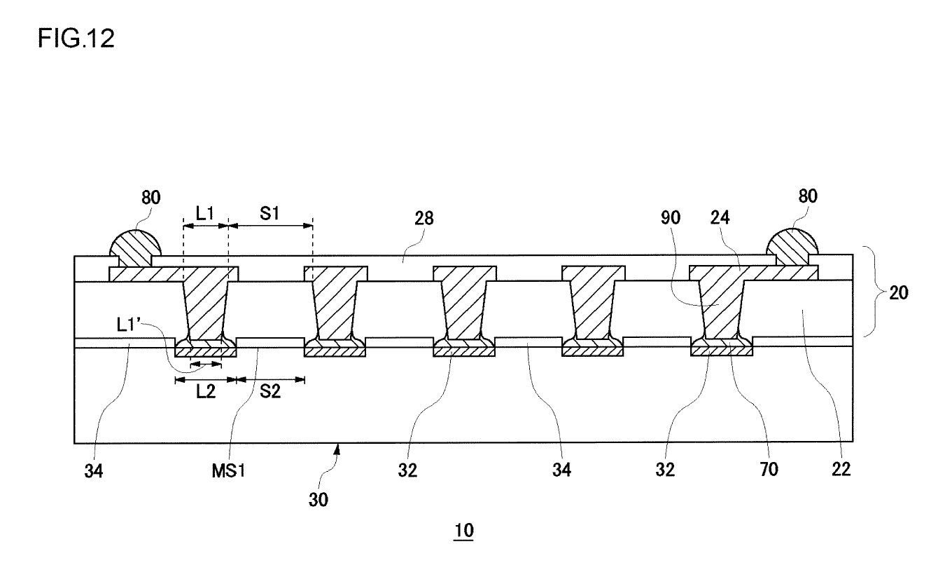

More specifically, as with a modification shown in FIG. 12, a gap is created between a side of the tip of the bump electrode 90 and the insulating resin layer 22. And the solder 70 enters into this gap, so that the solder 70 may be in contact with the tip of a side of the bump electrode 90. In such a case, too, the width of the side of the bump electrode 90 is smaller than the width L1 of the base of the bump electrode 90, and the width of the solder 70 in contact with the bump electrode 90 is smaller than the width L1 of the base of the bump electrode 90. That is, the solder 70 is prevented from expanding laterally (in the surface direction of the device mounting board 20) so that the width of the solder 70 at the bump electrode 90 side can lie within the width L2 of the device electrode 32.

(Application to Mobile Apparatus)

Next, a description will be given of a mobile apparatus (portable device) provided with a semiconductor module according to the above-described embodiments. The mobile apparatus presented as an example herein is a mobile phone, but it may be any electronic apparatus, such as a personal digital assistant (PDA), a digital video cameras (DVC), a music player or a digital still camera (DSC).

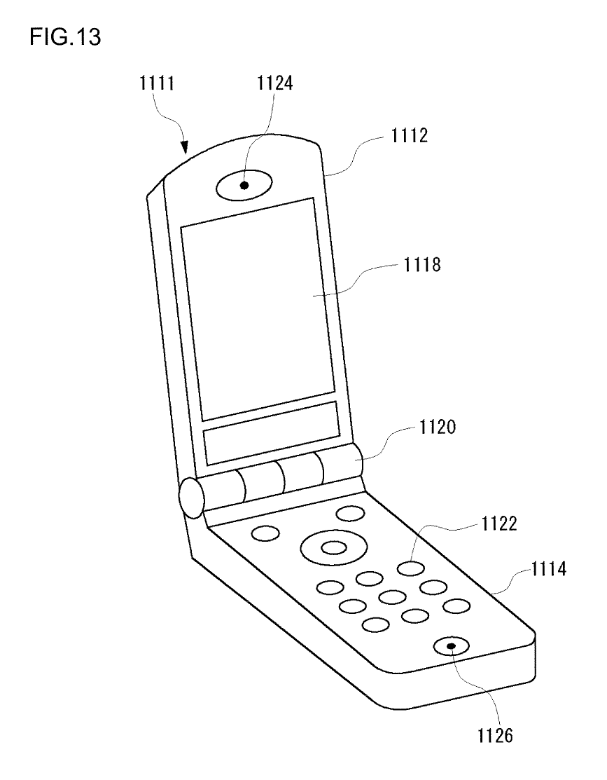

FIG. 13 illustrates a structure of a mobile phone provided with a semiconductor module 10 according to each of the above-described embodiments of the present invention. A mobile phone 1111 has a structure of a first casing 1112 and a second casing 1114 jointed together by a movable part 1120. The first casing 1112 and the second casing 1114 are turnable around the movable part 1120 as the axis. The first casing 1112 is provided with a display unit 1118 for displaying characters, images and other information and a speaker unit 1124. The second casing 1114 is provided with a control module 1122 with operation buttons and a microphone 1126. Note that a semiconductor module according to each embodiment of the present invention is mounted within a mobile phone 1111 such as this. The semiconductor module, according to each embodiment, mounted on a mobile phone may be used for a power supply circuit used to drive each circuit, an RF generation circuit for generating RF, a DAC, an encoder circuit, a driver circuit for a backlight used as the light source of a liquid-crystal panel used for a display of the mobile phone, and the like.

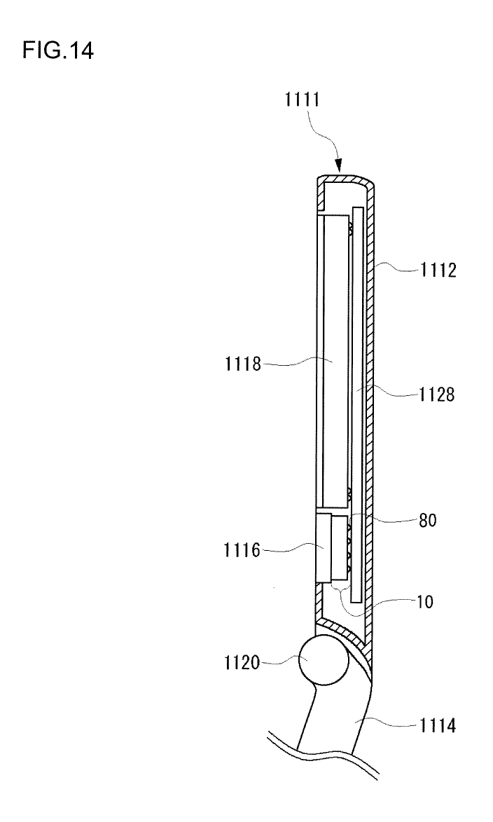

FIG. 14 is a partially schematic cross-sectional view (cross-sectional view of the first casing 1112) of the mobile phone shown in FIG. 28. A semiconductor module 10 according to any of the embodiments of the present invention is mounted on a printed circuit board 1128 via the solder balls 80 and is coupled electrically to a display unit 1118 and the like by way of the printed circuit board 1128. Also, a radiating substrate 1116, which may be a metallic substrate or the like, is provided on the back side of the semiconductor module 10 (opposite side of the solder balls 80), so that the heat generated from the semiconductor module 10, for example, can be efficiently released outside the first casing 1112 without getting trapped therein.

According to the mobile apparatus provided with a semiconductor module according to any of the above-described embodiments of the present invention, the following advantageous effects can be achieved.

In the semiconductor module 10, since the connection reliability between the substrate-side first electrode and the semiconductor-device-side second electrode is improved, the operation reliability of the semiconductor module 10. As a result, the operation reliability of the mobile apparatus incorporating such the semiconductor module 10 is improved.

The heat generated from the semiconductor module 10 can be efficiently released to the outside by way of the radiating substrate 1116. Thus, the rise in temperature of the semiconductor module 10 is suppressed and the heat stress between the conductive members and the wiring layers is reduced. Accordingly, as compared with a case where no radiating substrate 1116 is provided, the separation of the conductive members inside the semiconductor module from the wiring layers is prevented and therefore the reliability (heat resistance reliability) of the semiconductor module 10 is improved. As a result, the reliability (heat resistance reliability) of the mobile apparatus can be improved.

Since the semiconductor module 10 according to any of the above-described embodiments achieves reduction in size, the mobile apparatus incorporating such the semiconductor module 10 can be made thinner and smaller.

The present invention is not limited to the above-described embodiments only. It is understood that various modifications such as changes in design may be made based on the knowledge of those skilled in the art, and the embodiments added with such modifications are also within the scope of the present invention.

For example, in each of the above-described embodiments, solder is used to connect the electrode provided on the device mounting board 20 and the electrode provided on the semiconductor device 30, as the conductive connection member. A conductive paste such as silver paste may instead be used as the conductive connection member.

### DESCRIPTION OF THE REFERENCE NUMERALS

10 Semiconductor module

20 Device mounting board

22 Insulating resin layer

24, 26 Wiring layer

### INDUSTRIAL APPLICABILITY

The present invention may be applicable to a semiconductor module where a semiconductor device is mounted on a substrate.

1. A semiconductor module, comprising:
a substrate where a first electrode is provided;
a semiconductor device where a second electrode is provided; and
a conductive connection member connecting the first electrode and the second electrode,
wherein the width of the first electrode is narrower than that of the second electrode corresponding to the first electrode, in a cross section along a line connecting adjacent first electrodes at a shortest distance therebetween, and
the height of the first electrode is greater than the width of the first electrode.

2. A semiconductor module according to claim 1, wherein in the cross section connecting the adjacent first electrodes at the shortest distance therebetween,
said conductive connection member lies within a region connecting a base of the first electrode and an upper side of the second electrode.

3. A semiconductor module according to claim 1, wherein in the cross section connecting the adjacent first electrodes at the shortest distance therebetween,
a ratio (L1/S1) of width L1 of the first electrode over an interval S1 between the adjacent first electrodes is less than a ratio (L2/52) of width L2 of the second electrode corresponding to the first electrode over an interval S2 between adjacent second electrodes.

4. A semiconductor module according to claim 1, wherein in the cross section connecting the adjacent first electrodes at the shortest distance therebetween,
a side surface of the first electrode is tilted towards an electrode forming region.

5. A semiconductor module according to claim 3, wherein in the cross section connecting the adjacent first electrodes at the shortest distance therebetween,
a side surface of the first electrode is tilted towards an electrode forming region.

6. A semiconductor module according to claim 1, wherein the first electrode is a bump electrode that protrudes from a wiring layer provided on said substrate towards said semiconductor device.

7. A semiconductor module according to claim 3, wherein the first electrode is a bump electrode that protrudes from a wiring layer provided on said substrate towards said semiconductor device.

8. A semiconductor module according to claim 1, wherein in the cross section connecting the adjacent first electrodes at the shortest distance therebetween,
the first electrode is of an approximately triangular or trapezoidal shape.

9. A method for fabricating a semiconductor module, the method comprising:
a wiring forming process of patterning a wiring layer, including adjacent substrate electrodes, on one main surface of a substrate; and
a device mounting process of mounting a semiconductor device in a manner such that (1) a device electrode so provided in the semiconductor device as to correspond to the substrate electrode and (2) the substrate electrode are connected using a conductive connection member,
wherein the substrate electrode is formed, in said wiring forming process, in a manner such that the width of the substrate electrode is narrower than that of the device electrode corresponding to the substrate electrode, in a cross section along a line connecting the adjacent substrate electrodes at a shortest distance therebetween.
